(19) United States
(12) Patent Application Publication
(10) Pub. No.: US 2026/0106584 A1
(43) Pub. Date: Apr. 16, 2026

(54) TRANSIMPEDANCE AMPLIFIER ADAPTIVE TO INPUT CURRENT VARIATION AND OUTPUT VOLTAGE LEVEL SHIFT

(71) Applicant: Raytheon Company, Tewksbury, MA (US)

(72) Inventors: Zhaoyang Wang, Carlisle, MA (US); Matthew A. Morton, Lynnfield, MA (US)

(21) Appl. No.: 18/916,475

(22) Filed: Oct. 15, 2024

(51) Int. Cl. H03F 3/45

(52) U.S. Cl. CPC H03F 3/45475; H03F 2203/45274

(57) ABSTRACT

An apparatus includes a transimpedance amplifier having at least one input and an output. The apparatus also includes an adaptive input current variation circuit connected to the at least one input of the transimpedance amplifier and configured to receive at least one input current and adjust the at least one input current to a selected input current provided to the at least one input of the transimpedance amplifier.

### TECHNICAL FIELD

This disclosure relates generally to transimpedance amplifiers. More specifically, this disclosure relates to a transimpedance amplifier that is adaptive to input current variation and output voltage level shift.

### BACKGROUND

A transimpedance amplifier (TIA) is a device that converts an electrical current into an electrical voltage. Among other uses, a TIA can be used to provide an interface between a photonic integrated circuit and an analog-to-digital converter (ADC). Often times, a TIA needs to handle large currents produced by a photonic integrated circuit without using a direct current (DC) blocking capacitor. Also, the TIA may need to be able to level-shift to a desired DC output voltage level for use with different types of commercial off-the-shelf or other ADCs.

### SUMMARY

This disclosure relates to a transimpedance amplifier that is adaptive to input current variation and output voltage level shift.

In some examples, an apparatus includes a transimpedance amplifier having at least one input and an output. The apparatus also includes an adaptive input current variation circuit connected to the at least one input of the transimpedance amplifier and configured to receive at least one input current and adjust the at least one input current to a selected input current provided to the at least one input of the transimpedance amplifier.

Any single one or any combination of the following features may be used with the examples above. The apparatus may include a photonic integrated circuit configured to generate the at least one input current and an analog-to-digital converter configured to receive an output voltage. The adaptive input current variation circuit may include a resistor ladder configured to receive the at least one input current and measure an input voltage to the adaptive input current variation circuit. The adaptive input current variation circuit further may include an operational amplifier configured to compare the measured input voltage to a reference bias voltage and generate a first current control signal responsive thereto and a current source connected to the at least one input of the transimpedance amplifier and configured to drain an input DC current from the at least one input current responsive to the first current control signal. The adaptive input current variation circuit is further configured to drain an input dc current from the at least one input current. The level-shifted output voltage is adaptive responsive to a reference output voltage. The output voltage level shift circuit may include a resistor ladder connected to an output of the output voltage level shift circuit and configured to measure the level-shifted output voltage and a control circuit configured to compare the measured level-shifted output voltage to a reference output voltage and level-shift the measured level-shifted output voltage to the reference output voltage responsive to the comparison. The control circuit is configured to adaptively adjust the level-shifted output voltage from the transimpedance amplifier to substantially equal the reference output voltage. The adaptive input current variation circuit is configured to set a predetermined bias voltage that adapts to variations in the at least one input current.

In other examples, an apparatus includes a transimpedance amplifier having at least one input and an output. The apparatus also includes a transimpedance amplifier having at least one input and an output. The apparatus also includes an adaptive input current variation circuit connected to the at least one input of the transimpedance amplifier and configured to receive at least one input current and adjust the at least one input current to a selected input current provided to the at least one input of the transimpedance amplifier, where the adaptive input current variation circuit is further configured to drain an input DC current from the at least one input current.

Any single one or any combination of the following features may be used with the examples above. The adaptive input current variation circuit may include a resistor ladder configured to receive the at least one input current and measure an input voltage to the adaptive input current variation circuit. The adaptive input current variation circuit further may include an operational amplifier configured to compare the measured input voltage to a reference bias voltage and generate a first current control signal responsive thereto and a current source connected to the at least one input of the transimpedance amplifier and configured to drain an input DC current from the at least one input current responsive to the first current control signal. The adaptive input current variation circuit is configured to set a predetermined bias voltage that adapts to variations in the at least one input current.

In still other examples, a method for operating a transimpedance amplifier. The method also includes receiving at least one input current. The method also includes adjusting the at least one input current to a selected input current that is provided to at least one input of the transimpedance amplifier using an adaptive input current variation circuit. The method also includes outputting an output voltage from the output of the transimpedance amplifier responsive to the at least one input current.

Any single one or any combination of the following features may be used with the examples above. Adjusting the at least one input current may include measuring an input voltage to the adaptive input current variation circuit using a resistor ladder connected to the at least one input of the transimpedance amplifier. Adjusting the at least one input current further may include comparing the measured input voltage to a reference bias voltage using an operational amplifier, generating a first current control signal responsive to the comparison using the operational amplifier and draining an input DC current from the at least one input current responsive to the first current control signal using a current source connected to the at least one input of the transimpedance amplifier. Adjusting the at least one input current may include draining an input dc current from the at least one input current using the adaptive input current variation circuit. The adaptive input current variation circuit is configured to set a predetermined bias voltage that adapts to variations in the at least one input current. The level-shifted output voltage is adaptive responsive to a reference output voltage. Generating the level-shifted output voltage may include measuring the level-shifted output voltage of the transimpedance amplifier using a resistor ladder connected to the output of the transimpedance amplifier, comparing the measured level-shifted output voltage to the reference output voltage and level-shifting the measured level-shifted output voltage to the reference output voltage responsive to the comparison using a control circuit.

Other technical features may be readily apparent to one skilled in the art from the following figures, descriptions, and claims.

### BRIEF DESCRIPTION OF THE DRAWINGS

For a more complete understanding of this disclosure and its advantages, reference is now made to the following description taken in conjunction with the accompanying drawings, in which like reference numerals represent like parts:

FIG. 1 illustrates an example transimpedance amplifier (TIA) interconnected between a photonic integrated circuit and an analog-to-digital converter in accordance with this disclosure;

FIG. 2 illustrates an example TIA having an associated adaptive input current variation circuit and output voltage level shift circuit in accordance with this disclosure;

FIG. 3 illustrates an example of the adaptive input current variation circuit of FIG. 2 in accordance with this disclosure;

FIG. 4 illustrates example operation of the circuit of FIG. 3 in accordance with this disclosure;

FIG. 5 illustrates an example of the output voltage level shift circuit of FIG. 2 in accordance with this disclosure; and

FIG. 6 illustrates example operation of the circuit of FIG. 5 in accordance with this disclosure.

### DETAILED DESCRIPTION

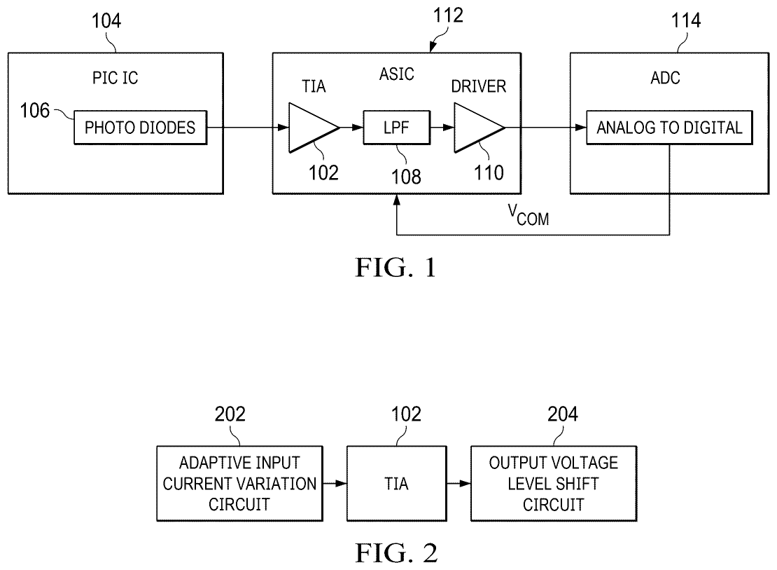

FIGS. 1 through 6, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

FIG. 1 illustrates an example transimpedance amplifier (TIA) 102 interconnected between a photonic integrated circuit (PIC) 104 and an analog-to-digital converter (ADC) 114 in accordance with this disclosure. More specifically, the TIA 102 in this example has an input connected to an output of the PIC 104. The PIC 104 includes one or more photodiodes 106 therein to provide electrical current output to the TIA 102. The TIA 102 has its output connected to a low pass filter 108, and an output of the low pass filter 108 is connected to a driver circuit 110. In some embodiments, the TIA 102, low pass filter 108, and driver circuit 110 may be implemented within an application-specific integrated circuit (ASIC) 112. An output from the ASIC 112 is provided to the ADC 114. The TIA 102 here therefore provides an interface between the PIC 104 and the ADC 114.

In some embodiments, the TIA 102 needs to be able to handle large DC currents that are produced by the photodiodes 106 within the PIC 104. Previous approaches have made use of blocking capacitors in order to block large DC currents. However, the implementation described here handles the large currents from the PIC 104 without the use of DC blocking capacitors. Additionally, the TIA 102 can have the ability to level-shift its output to a desired DC output voltage level in order to interact with different commercial off-the-shelf or other ADCs 114.

FIG. 2 illustrates an example TIA 102 having an associated adaptive input current variation circuit 202 and output voltage level shift circuit 204 in accordance with this disclosure. As shown in FIG. 2, the adaptive input current variation circuit 202 is connected to the input of the TIA 102. The adaptive input current variation circuit 202 enables the handling of large DC currents produced by the PIC 104 or other source and does not utilize DC blocking capacitors. For example, the adaptive input current variation circuit 202 can provide a current source to drain the input DC current from the PIC 104 prior to the current entering into the TIA 102. The current source can be controlled responsive to a comparison of the input voltage caused by the input current from the PIC 104 with respect to a desired input bias voltage Vbias. The adaptive input current variation circuit 202 can also provide or be used in conjunction with a feedback network that controls the current source adaptive to the input DC current changes and adjusts the input bias voltage back to a desired voltage bias in order to maintain optimum performance of the TIA 102. Such a bias control and DC current removal technique can reduce overall TIA noise by adaptively cancelling the impact the DC current would otherwise have on the optimal TIA operating current. In some embodiments, the adaptive input current variation circuit 202 enables the TIA to handle between 0.1-10 mA DC input current and maintain 3V at the input.

The output voltage level shift circuit 204 shifts an output DC voltage from the TIA 102 up or down adaptively based on different requirements of different commercial off-the-shelf or other ADCs 114. This enables the connection of different ADCs 114 to the TIA 102. In some cases, the output voltage level shift circuit 204 utilizes a pair of operational amplifiers as described below in order to make the output voltage level shift circuit 204 adaptive to a desired output voltage for different ADCs 114. The output voltage level shift circuit 204 may also allow for bidirectional DC voltage level shift at its output voltage node. Such a bidirectional voltage level shift can reduce noise and increase voltage shift accuracy toward a target voltage of the connected ADC 114. In some cases, the output voltage level shift circuit 204 may enable the output of the TIA 102 to be shifted to an optimum common voltage level (Vcom) of the connected ADC 114, such as in the range of 0.45 V to 1.4 V.

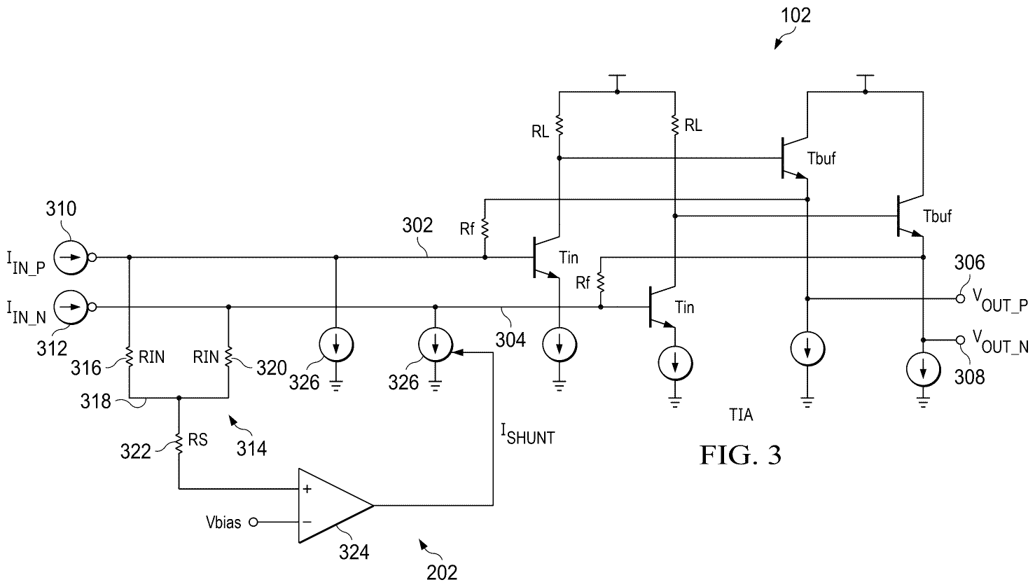

FIG. 3 illustrates an example of the adaptive input current variation circuit 202 of FIG. 2 in accordance with this disclosure. As shown in FIG. 3, the adaptive input current variation circuit 202 receives inputs at nodes 302, 304 and generates outputs at nodes 306, 308. Input currents from the photodiodes 106 of the PIC 104 are respectively provided to the nodes 302, 304 as input currents 310, 312. An input voltage provided by the input currents 310, 312 is measured by a resistor ladder 314 having a resistor 316 connected between the node 302 and a node 318, a resistor 320 connected between the node 304 and the node 318, and a resistor 322 connected between the node 318 and a non-inverted input of an operational amplifier 324. The inverted input of the operational amplifier 324 is connected to a reference voltage Vbias representing the desired bias voltage toward which the input voltage detected by the resistor ladder 314 is driven. The output of the operational amplifier 324 is connected to a current source 326 connected to the nodes 302, 304. The current source 326 is driven by the output Ishunt of the operational amplifier 324 in order to equalize the input voltage measured by the resistor ladder 314 with respect to the bias voltage Vbias.

The current source 326 is controlled to drain the input DC current provided from the input currents 310 and 312 from the photodiodes 106 of the PIC 104. The current source 326 can drain the input DC current from the input currents 310 and 312 prior to reaching the TIA 102. The operational amplifier 324 controls the amount of current generated by the current source 326, thereby controlling the amount of current that is drained from the input currents 310 and 312. For example, the operational amplifier 324 may generate its control signal by comparing the input voltage to the TIA 102 measured by the resistor ladder 314 to a desired input voltage bias level Vbias. When the input DC current to the TIA 102 varies, the input voltage may be different from the desired bias voltage Vbias, and the feedback network of the TIA design may make the control of the current source 326 adaptive to the input DC current change in order to pull the input voltage of the TIA 102 back to the desired input voltage bias Vbias. This helps to maintain improved or optimal performance of the TIA 102 responsive to the changing current levels from input currents 310, 312. In some cases, using the described adaptive input current variation circuit 202, a DC sink current may vary between 0.1-50 mA, and the AC input current may vary between 0.1-50 mA.

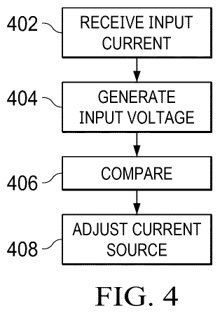

FIG. 4 illustrates example operation of the circuit 202 of FIG. 3 in accordance with this disclosure. As shown in FIG. 4, the input currents 310, 312 are initially received at the nodes 302, 304 of the adaptive input current variation circuit 202 at step 402. The input currents are used to determine an input voltage through the resistor ladder 314 at step 404. The determined input voltage across the resistor ladder 314 is compared with the bias voltage Vbias using the operational amplifier 324 at step 406. The operational amplifier 324 generates a control signal to the current source 326 in order to adjust the drain current from the nodes 302, 304 at step 408.

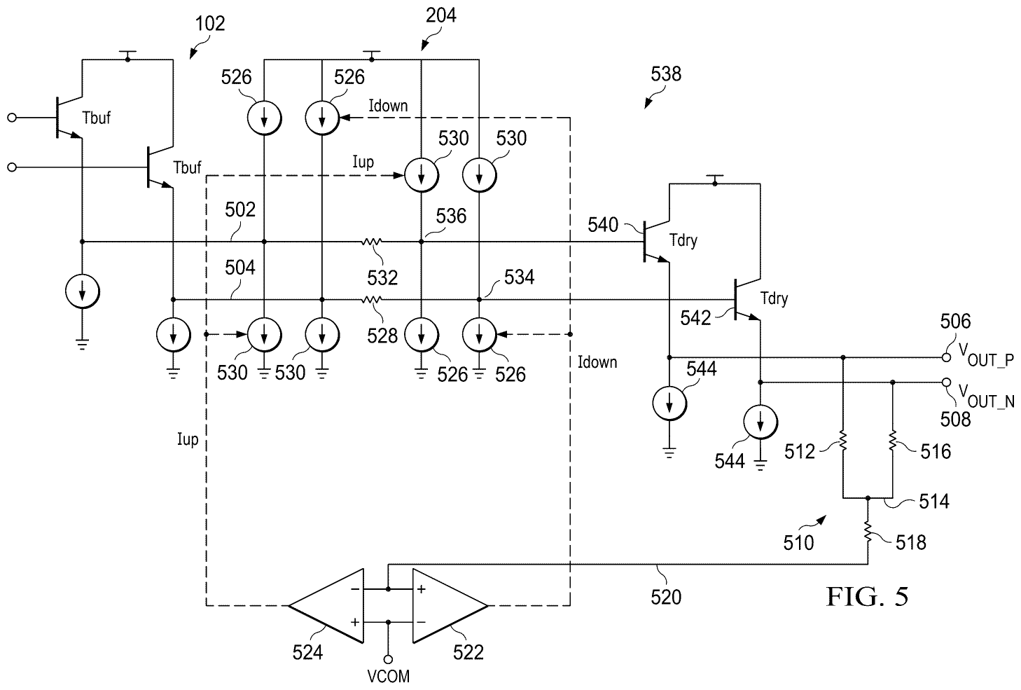

FIG. 5 illustrates an example of the output voltage level shift circuit 204 of FIG. 2 in accordance with this disclosure. As shown in FIG. 5, an output of the output voltage level shift circuit 204 is connected to nodes 502, 504 of the TIA 102 in order to adjust the level of the TIA's output voltage Vout between nodes 502, 504 to a desired output voltage level. In some cases, the desired output voltage level is based on the ADC 114 to which the TIA 102 may be connected. The output voltage Vout is measured across nodes 506, 508 using a resistor ladder 510 having a resistor 512 connected between the node 506 and a node 514, a resistor 516 connected between the node 508 and the node 514, and a resistor 518 connected between the node 514 and a node 520. The node 520 connects to a non-inverted input of an operational amplifier 522 and to an inverted input of an operational amplifier 524. The non-inverted input of the operational amplifier 522 connects to a desired output voltage level Vcom, and the inverted input of the operational amplifier 524 also connects to the desired output voltage level Vcom.

An output of the operational amplifier 522 provides a control signal Idown that is used for controlling a first current source 526 to flow current through a level shift resistor 528, which lowers the output DC voltage level between the nodes 506 and 508. The operational amplifier 524 controls a current source 530 to flow current through a level shift resistor 532 to raise the output DC voltage between the nodes 506 and 508. The level shift resistor 528 is connected between the node 504 and a node 534, and the level shift resistor 532 is connected between the node 502 and a node 536. The nodes 536 and 534 represent the inputs of a driver circuit 538, which includes a transistor 540, a transistor 542, and a current source 544. The output of the driver circuit 538 at the nodes 506 and 508 are connected to the ADC 114. The operational amplifiers 522 and 524 work together to make the voltage output of the TIA 102 adaptive to the desired Vcom reference voltage for the ADC 114. As a result, the value of Vcom can be set based on the specific ADC 114 in use.

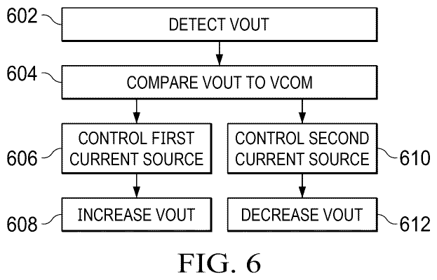

FIG. 6 illustrates example operation of the circuit 204 of FIG. 5 in accordance with this disclosure. As shown in FIG. 6, an output voltage Vout at the output of the driver circuit 538 is detected using the resistor ladder 510 at step 602. The detected output voltage Vout is compared to the desired output voltage Vcom by each of the operational amplifiers 522 and 524 at step 604. With respect to the output of the operational amplifier 524, the current source 530 is controlled at step 606, which allows the current source 530 to increase the output voltage at step 608. Concurrently, responsive to the output of the operational amplifier 522, the current source 526 is controlled at step 610, which allows the current source 526 to decrease the output voltage at step 612. The operational amplifiers 522, 524 working together are able to achieve the desired output voltage between the nodes 506 and 508, and the desired output voltage is provided to the connected ADC 114.

It may be advantageous to set forth definitions of certain words and phrases used throughout this patent document. The term “couple” and its derivatives refer to any direct or indirect communication between two or more components, whether or not those components are in physical contact with one another. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S. C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S. C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. An apparatus comprising:
a transimpedance amplifier having at least one input and an output; and
an adaptive input current variation circuit connected to the at least one input of the transimpedance amplifier and configured to receive at least one input current and adjust the at least one input current to a selected input current provided to the at least one input of the transimpedance amplifier.

2. The apparatus of claim 1, further comprising:
a photonic integrated circuit configured to generate the at least one input current; and
an analog-to-digital converter configured to receive an output voltage.

3. The apparatus of claim 1, wherein the adaptive input current variation circuit comprises a resistor ladder configured to receive the at least one input current and measure an input voltage to the adaptive input current variation circuit.

4. The apparatus of claim 3, wherein the adaptive input current variation circuit further comprises:
an operational amplifier configured to compare the measured input voltage to a reference bias voltage and generate a first current control signal responsive thereto; and
a current source connected to the at least one input of the transimpedance amplifier and configured to drain an input DC current from the at least one input current responsive to the first current control signal.

5. The apparatus of claim 1, wherein the adaptive input current variation circuit is further configured to drain an input DC current from the at least one input current.

6. The apparatus of claim 1 further comprising an output voltage level shift circuit connected to the output of the transimpedance amplifier, the output voltage level shift circuit configured to generate a level-shifted output voltage, wherein the level-shifted output voltage is adaptive responsive to a reference output voltage.

7. The apparatus of claim 6, wherein the output voltage level shift circuit comprises:
a resistor ladder connected to an output of the output voltage level shift circuit and configured to measure the level-shifted output voltage; and
a control circuit configured to compare the measured level-shifted output voltage to a reference output voltage and level-shift the measured level-shifted output voltage to the reference output voltage responsive to the comparison.

8. The apparatus of claim 7, wherein the control circuit is configured to adaptively adjust the level-shifted output voltage from the transimpedance amplifier to substantially equal the reference output voltage.

9. The apparatus of claim 1, wherein the adaptive input current variation circuit is configured to set a predetermined bias voltage that adapts to variations in the at least one input current.

10. An apparatus comprising:
a transimpedance amplifier having at least one input and an output; and
an adaptive input current variation circuit connected to the at least one input of the transimpedance amplifier and configured to receive at least one input current and adjust the at least one input current to a selected input current provided to the at least one input of the transimpedance amplifier, wherein the adaptive input current variation circuit is further configured to drain an input DC current from the at least one input current.

11. The apparatus of claim 10, wherein the adaptive input current variation circuit comprises a resistor ladder configured to receive the at least one input current and measure an input voltage to the adaptive input current variation circuit.

12. The apparatus of claim 11, wherein the adaptive input current variation circuit further comprises:
an operational amplifier configured to compare the measured input voltage to a reference bias voltage and generate a first current control signal responsive thereto; and
a current source connected to the at least one input of the transimpedance amplifier and configured to drain an input DC current from the at least one input current responsive to the first current control signal.

13. The apparatus of claim 10, wherein the adaptive input current variation circuit is configured to set a predetermined bias voltage that adapts to variations in the at least one input current.

14. A method for operating a transimpedance amplifier, the method comprising:
receiving at least one input current;
adjusting the at least one input current to a selected input current that is provided to at least one input of the transimpedance amplifier using an adaptive input current variation circuit; and
outputting an output voltage from the output of the transimpedance amplifier responsive to the at least one input current.

15. The method of claim 14, wherein adjusting the at least one input current comprises measuring an input voltage to the adaptive input current variation circuit using a resistor ladder connected to the at least one input of the transimpedance amplifier.

16. The method of claim 15, wherein adjusting the at least one input current further comprises:
comparing the measured input voltage to a reference bias voltage using an operational amplifier;
generating a first current control signal responsive to the comparison using the operational amplifier; and
draining an input DC current from the at least one input current responsive to the first current control signal using a current source connected to the at least one input of the transimpedance amplifier.

17. The method of claim 14, wherein adjusting the at least one input current comprises draining an input DC current from the at least one input current using the adaptive input current variation circuit.

18. The method of claim 14, wherein the adaptive input current variation circuit is configured to set a predetermined bias voltage that adapts to variations in the at least one input current.

19. The method of claim 14 further comprising generating a level-shifted output voltage at an output of the transimpedance amplifier using an output voltage level shift circuit, wherein the level-shifted output voltage is adaptive responsive to a reference output voltage.

20. The method of claim 19, wherein generating the level-shifted output voltage comprises:
measuring the level-shifted output voltage of the transimpedance amplifier using a resistor ladder connected to the output of the transimpedance amplifier;
comparing the measured level-shifted output voltage to the reference output voltage; and
level-shifting the measured level-shifted output voltage to the reference output voltage responsive to the comparison using a control circuit.
